(19) United States
(12) Patent Application Publication
(10) Pub. No.: US 2026/0324316 A1
(43) Pub. Date: Oct. 15, 2026

(54) Substrate Processing Method, Substrate Processing Device, and Substrate Processing System

(71) Applicant: Tokyo Electron Limited, Tokyo (JP)

(72) Inventors: Kenji OUCHI, Yamanashi (JP); Takahiro MIYAHARA, Albany, NY (US); Susumu YAMAUCHI, Yamanashi (JP); Takahiro OGINO, Yamanashi (JP); Kota UMEZAWA, Yamanashi (JP); Katsutoshi ISHII, Tokyo (JP); Ryota IFUKU, Yamanashi (JP); Yoshimasa WATANABE, Yamanashi (JP)

(21) Appl. No.: 19/696,084

(22) Filed: Jun. 2, 2026

Related U.S. Application Data
(63) Continuation of application No. PCT/JP2024/042503, filed on Dec. 2, 2024.

(30) Foreign Application Priority Data
Dec. 14, 2023 (JP) 2023-210808

(51) Int. Cl. H10P 14/69; H10P 14/60; H10P 74/20; H10P 95/90

(52) U.S. Cl. CPC H10P 14/6903; H10P 14/6336; H10P 74/203; H10P 95/90

(57) ABSTRACT

Provided is a substrate processing method comprising: preparing a substrate having a first surface on which a device is to be formed; and forming a silicon-containing film on a second surface opposite to the first surface of the substrate using a higher-order silane gas as a film forming gas at a temperature at which the higher-order silane gas liquefies.

### CROSS-REFERENCE TO RELATED APPLICATIONS

This application is a bypass continuation application of International Application No. PCT/JP2024/042503 having an international filing date of Dec. 2, 2024 and designating the United States, the International Application being based upon and claiming the benefit of priority from Japanese Patent Application No. 2023-210808 filed on Dec. 14, 2023, the entire contents of which are incorporated herein by reference.

### TECHNICAL FIELD

The present disclosure relates to a substrate processing method, a substrate processing apparatus, and a substrate processing system.

### BACKGROUND

Japanese Laid-open Patent Publication No. 2020-150133 discloses a technique for applying stress to a substrate by forming, on the backside of the substrate, a dummy film having compressive stress, such as an SiO₂ film or an SiN film, by ALD or CVD.

### SUMMARY

The present disclosure provides a technique capable of generating large stress on a second surface of a substrate opposite to a first surface on which a device is formed.

In accordance with an aspect of the subject disclosure, there is provided a substrate processing method comprising: preparing a substrate having a first surface on which a device is to be formed; and forming a silicon-containing film on a second surface opposite to the first surface of the substrate using a higher-order silane gas as a film forming gas at a temperature at which the higher-order silane gas liquefies.

### BRIEF DESCRIPTION OF THE DRAWINGS

FIG. 1 is a flowchart illustrating a substrate processing method according to a first embodiment.

FIG. 2A is a process cross-sectional view illustrating the substrate processing method according to the first embodiment.

FIG. 2B is a process cross-sectional view illustrating the substrate processing method according to the first embodiment.

FIG. 3 is a cross-sectional view illustrating a base of a sample used in a test for checking stress generated on a second surface of a substrate due to shrinkage of a silicon-containing film formed in the first embodiment.

FIG. 4 is a cross-sectional view illustrating a sample used in a test for checking stress generated on the second surface of the substrate, the sample being formed by forming a silicon-containing film on the base of FIG. 3.

FIG. 5 is a diagram illustrating the relationship between an annealing temperature and a Raman shift in the case of performing annealing on the sample of FIG. 4.

FIG. 6 is a cross-sectional view schematically illustrating a stress state of the second surface of the substrate in an initial state (A in FIG. 5) before the formation of the silicon-containing film used for obtaining the relationship of FIG. 5.

FIG. 7 is a diagram illustrating stress on the second surface of the substrate in the case where an annealing temperature is lower than 100 °C (B and C in FIG. 5).

FIG. 8 is a diagram illustrating stress on the second surface of the substrate in the case where the annealing temperature is within a range of 100 °C to 200 °C and the Raman shift becomes positive (D in FIG. 5).

FIG. 9 is a cross-sectional view illustrating an example of a substrate processing apparatus used for implementing the first embodiment.

FIG. 10 is a flowchart illustrating a substrate processing method according to a second embodiment.

FIG. 11A is a process cross-sectional view illustrating the substrate processing method according to the second embodiment.

FIG. 11B is a process cross-sectional view illustrating the substrate processing method according to the second embodiment.

FIG. 11C is a process cross-sectional view illustrating the substrate processing method according to the second embodiment.

FIG. 12 is a plan view schematically illustrating an example of a substrate processing system used for implementing the second embodiment.

FIG. 13 is a cross-sectional view illustrating an example of an annealing apparatus used in the substrate processing system of FIG. 12.

FIG. 14 is a flowchart illustrating a substrate processing method according to a third embodiment.

FIG. 15A is a process cross-sectional view illustrating the substrate processing method according to the third embodiment.

FIG. 15B is a process cross-sectional view illustrating the substrate processing method according to the third embodiment.

FIG. 15C is a process cross-sectional view illustrating the substrate processing method according to the third embodiment.

FIG. 15D is a process cross-sectional view illustrating the substrate processing method according to the third embodiment.

FIG. 16 is a plan view schematically illustrating an example of a substrate processing system used for implementing the third embodiment.

FIG. 17 is a cross-sectional view schematically illustrating a stress measuring apparatus used in the substrate processing system of FIG. 16.

### DETAILED DESCRIPTION

Hereinafter, embodiments will be described in detail with reference to the accompanying drawings.

### Substrate Processing Method

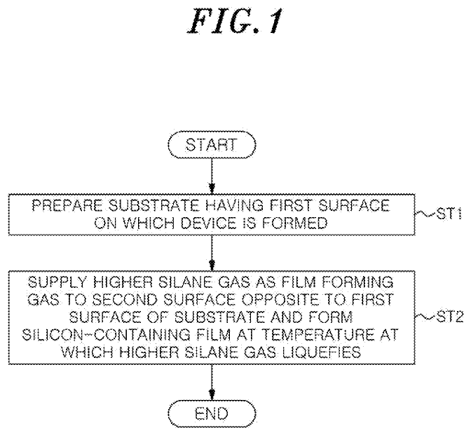

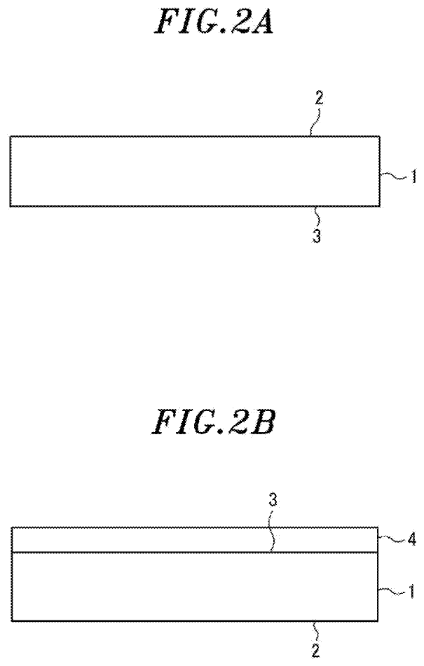

FIG. 1 is a flowchart illustrating a substrate processing method according to the first embodiment. FIGS. 2A to 2B are process cross-sectional views thereof.

In the present embodiment, first, a substrate 1 having a first surface 2 on which a device is formed is prepared (step ST1, FIG. 2A). Next, a higher-order silane gas is supplied as a film forming gas to a second surface 3 opposite to the first surface 2 of the substrate 1, thereby forming a silicon-containing film 4 at a temperature at which the higher-order silane gas liquefies (step ST2, FIG. 2B).

In step ST1, the substrate 1 is not particularly limited, but may be typically a semiconductor substrate (wafer). A device may or may not be actually formed on the first surface 2 of the substrate, and the substrate may be in the middle of a process of forming a device.

In step ST2, a higher-order silane gas is used as a film forming gas, and the silicon-containing film 4 is formed on the second surface 3 of the substrate 1 at a temperature at which the higher-order silane gas liquefies. The silicon-containing film 4 may be formed on the entire surface of the second surface 3, or may be formed on a part of the second surface 3.

The higher-order silane gas can liquefy at a practical temperature of about −30 °C. By performing film formation at a temperature at which the higher-order silane gas liquefies, a film in a state where low-molecular-weight components remain in the film is formed. Therefore, when energy such as heat or light is applied to the obtained silicon-containing film, a large amount of components in the film are vaporized, thereby causing the film to aggregate and shrink significantly. Due to the shrinkage, large stress can be generated on the second surface 3 of the substrate 1. In other words, the silicon-containing film 4 formed using the higher-order silane gas at a temperature at which the higher-order silane gas liquefies can generate high stress in the substrate.

The process of step ST2 can be performed, for example, by placing the substrate on a placing table in a chamber with the second surface facing upward, maintaining the substrate on the placing table at a temperature at which the higher-order silane gas liquefies, introducing the higher-order silane gas into the chamber, and supplying the higher-order silane gas to the second surface of the substrate in a plasma-excited state. In this case, by allowing a coolant to flow through the placing table, the substrate can be maintained at a temperature at which the higher-order silane gas liquefies, for example, −30 °C. The pressure in the chamber at this time may be within a range of 10 Torr or less, for example, 1 Torr.

By exciting the higher-order silane gas with plasma, a film skeleton is formed by gas-phase polymerization even at a low temperature, thereby allowing film formation to proceed. Further, by using plasma, a film with high adhesion can be obtained. The plasma is not particularly limited, and various types of plasma such as capacitively coupled plasma, inductively coupled plasma, and microwave plasma can be used.

The higher-order silanes are represented by the general formula SiₙH₂ₙ₊₂ (n being a positive integer of 2 or more), such as disilane (Si₂H₆), trisilane (Si₃H₈), and tetrasilane (Si₄H₁₀). The boiling points of Si₂H₆, Si₃H₈, and Si₄H₁₀ are −14.5 °C, 52.8 °C, and 108.1 °C, respectively, all of which are sufficiently higher than the boiling point of monosilane (SiH₄), which is −112 °C. As described above, they can stably liquefy at a practical temperature of about −30 °C. The higher silane in which n is 4 or more can achieve a higher shrinkage capability.

The gas used during film formation may be, other than the higher-order silane gas, H₂ gas or a rare gas (e.g., Ar gas) as a plasma generation gas. When only the higher-order silane gas is used as the film forming gas, or when H₂ gas is added to the higher-order silane gas, the silicon-containing film is a Si-based film, and becomes an Si film after components in the film are vaporized. An oxygen-containing gas may be further added as the film forming gas to make the silicon-containing film an SiO₂-based film that eventually becomes an SiO₂ film. By changing the film quality of the silicon-containing film, the shrink characteristics change, and the capability to generate stress on the second surface of the substrate can be adjusted.

Since the silicon-containing film 4 can generate high stress, the film may be thinner than a film formed by conventional CVD or ALD in order to generate desired stress. The thickness of the silicon-containing film 4 may be appropriately set according to the stress to be generated, and may be within a range of 1 nm to 10,000 nm.

In an actual case, tetrasilane was used as the higher-order silane serving as the film forming gas, and the substrate was maintained at −30 °C at which the higher-order silane gas liquefies, on a placing table in a chamber. Then, the higher-order silane gas was supplied to the substrate in a plasma-excited state to form the silicon-containing film. Then, the capability of generating stress on the second surface of the substrate was investigated.

Specifically, after the formation of the silicon-containing film, the substrate on which the silicon-containing film was formed was annealed on the stage at various temperatures, and the desorbed gases at that time were analyzed by thermal desorption spectroscopy (TDS). As a result, it was confirmed that H₂ gas and silane-based gases such as SiH₄, Si₂H₆, and Si₃H₈ were desorbed. Similarly, the substrate was annealed at various temperatures and, then, the film structure changes were checked by Fourier transform infrared spectroscopy (FT-IR). As a result, it was confirmed that the intensity of SiHₓ (SiH, SiH₂, SiH₃, (SiH₂)ₙ, or the like) decreased as the annealing temperature increased. From these results, it was confirmed that the shrinkage of the silicon-containing film formed according to the present embodiment occurs due to the desorption of H₂ gas and silane-based gases.

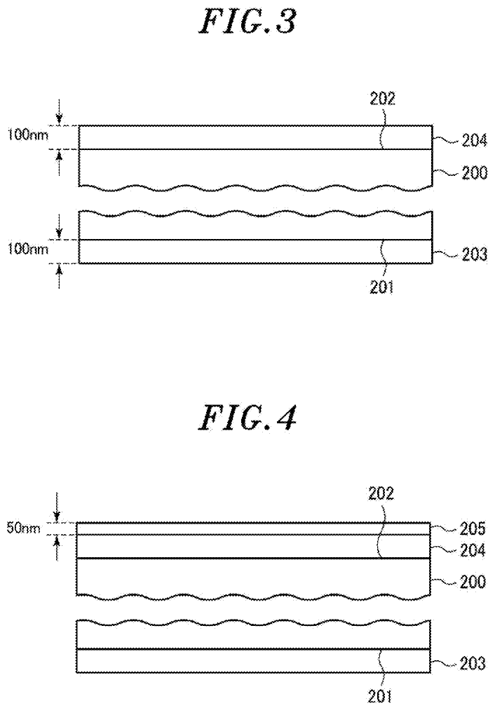

Next, the stress generated on the second surface of the substrate due to the shrinkage of the silicon-containing film formed according to the present embodiment was checked. Here, as shown in FIG. 3, a base in which thermal oxide films 203 and 204 having a thickness of 100 nm were formed on both a first surface 201 and a second surface 202 of a Si substrate 200 was prepared. As shown in FIG. 4, a sample in which a silicon-containing film 205 having a thickness of 50 nm was formed on a thermal oxide film 204 on the second surface 202 side of the Si substrate 200 was prepared. The thermal oxide film was formed to distinguish the silicon-containing film from the Si substrate because the silicon-containing film is a Si-based film.

The sample was annealed, and the stress generated on the second surface 202 of the substrate 200 due to the shrinkage of the silicon-containing film 205 was evaluated. The stress was measured by cross-sectional Raman measurement (Raman spectroscopy). The stress generated in the substrate due to the shrinkage of the silicon-containing film can be calculated based on the shift (Raman shift) from 520 (cm⁻¹), which is the peak of Si crystal (stress-free crystal) in the spectrum of Raman-scattered light (Raman spectrum). Specifically, when ν represents the Raman shift (cm⁻¹) and Σ represents the stress (MPa), the relationship shown in the following Eq. (1) is obtained. Therefore, the stress applied to the second surface of the substrate by the shrinkage of the silicon-containing film can be calculated based on the Raman shift from Eq. (1).

ν=−1.93×10⁻³ Σ (1)

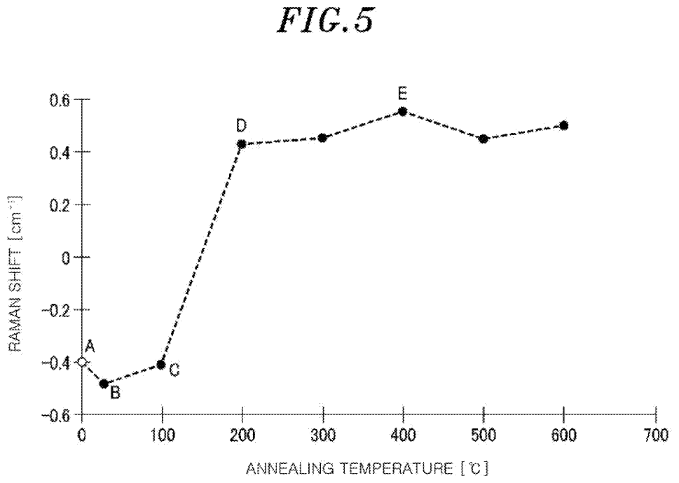

FIG. 5 is a diagram showing the relationship between the annealing temperature and the Raman shift in the case of performing annealing on the above sample. The annealing time was about one hour at each temperature. For the Raman shift on the vertical axis, the silicon peak of 520 (cm⁻¹) is set to 0, where negative indicates the tensile direction and positive indicates the compressive direction. Although the substrate stress is reduced by the thermal oxide film, correction was made here to eliminate the influence of the thermal oxide film. In FIG. 5, A represents the Raman shift value in an initial state in which no silicon-containing film is formed for comparison, and the others represent the Raman shift values in a state where annealing was performed at a predetermined temperature after the formation of the silicon-containing film.

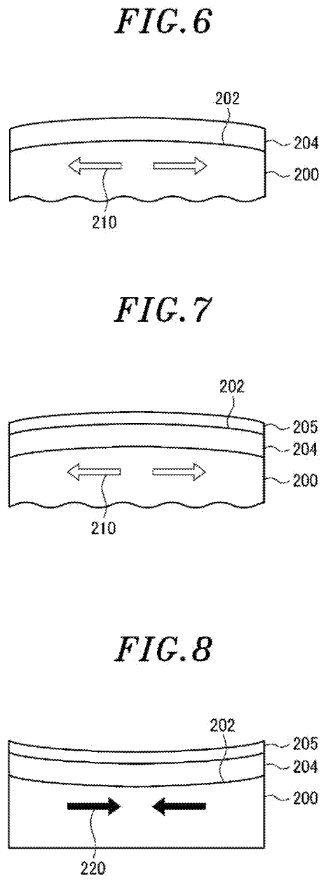

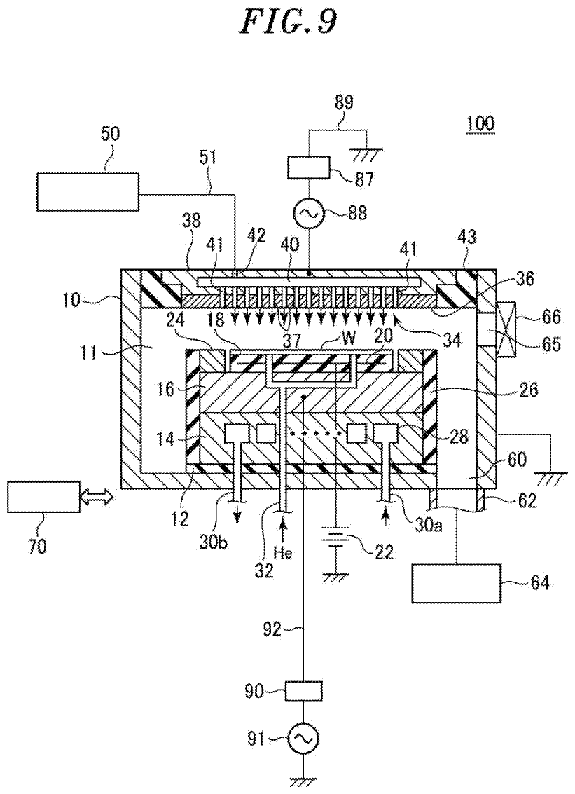

As shown in FIG. 5, in A, which is the initial state where no silicon-containing film is formed, the Raman shift of the substrate is −0.4 cm⁻¹. In other words, in the initial state, as shown in FIG. 6, a tensile stress 210 of about 200 MPa is generated on the second surface 202 of the substrate 200. After the silicon-containing film 205 is formed, the Raman shift slightly increases to −0.5 cm⁻¹, and remains negative at the annealing temperature below 100 °C (B and C in FIG. 5). In other words, as shown in FIG. 7, a state in which the tensile stress 210 is generated on the second surface 202 of the substrate 200 is maintained. However, the Raman shift changes significantly at the annealing temperature within a range of 100 °C and 200 °C, and becomes positive at 200 °C (D in FIG. 5). In other words, as shown in FIG. 8, the stress generated on the second surface 202 of the substrate 200 changes from the tensile stress 210 to a compressive stress 220. At the annealing temperature of 200 °C or higher, the Raman shift does not change significantly, but the Raman shift reaches a maximum value of +0.5 cm⁻¹ or more at 400 °C (E in FIG. 5). From this, it was confirmed that by annealing the silicon-containing film at a temperature of about 100 °C to 400 °C, particularly about 100 °C to 200 °C, the Raman shift changes from approximately −0.5 cm⁻¹ to +0.5 cm⁻¹, and the amount of change is about 1.0 cm⁻¹. The stress calculated from the amount of change in the Raman shift using Eq. (1) was 500 MPa or more, confirming that extremely large stress can be generated with a relatively thin film thickness of 50 nm.

In other words, it was confirmed that the silicon-containing film formed according to the present embodiment using a higher-order silane gas as a film forming gas and formed on the substrate at a temperature at which the higher silane liquefies is a film capable of generating extremely large stress on the substrate.

Conventionally, it has been known that film stress is applied to a substrate during the process of forming a device on one surface (first surface) of a wafer as a substrate due to repeated film formation and pattern formation by etching. In order to reduce the influence of the stress, it is effective to increase the thickness of the wafer as the substrate, but such a solution cannot be applied to technologies that require thinning of a wafer, such as wafer bonding techniques that have recently been employed. In addition, the presence of multiple stressed films causes pattern shifts, misalignment during exposure, and the like. Therefore, as disclosed in Japanese Laid-open Patent Publication No. 2020-150133, a technology for reducing the stress of the substrate by forming a film on the second surface opposite to the first surface of the substrate to generate stress in the substrate has been proposed.

However, conventionally, as disclosed in Japanese Laid-open Patent Publication No. 2020-150133, the film formed on the second surface is formed by general CVD or ALD. In this case, it is difficult to generate large stress in the substrate, and it is necessary to increase the film thickness. In the case of forming a film by CVD or ALD, the compressive stress generated in the substrate can be increased by performing the film formation at a high temperature. However, such an effect is limited, and the film formation at a high temperature is generally restricted due to its influence on the devices.

In contrast, in the present embodiment, by using a higher-order silane gas as the film forming gas and performing film formation on the second surface of the substrate at a temperature at which the higher-order silane gas liquefies, a silicon-containing film having a high shrinking capability can be obtained. This film can shrink significantly by annealing or the like, which makes it possible to apply large stress to the substrate. Therefore, desired stress can be applied to the substrate without increasing the film thickness as in the case of films formed by general CVD or ALD. Since the film is formed at a low temperature, disadvantages caused by high-temperature film formation do not occur.

### Substrate Processing Apparatus

FIG. 9 is a cross-sectional view illustrating an example of a substrate processing apparatus used for implementing the first embodiment. In the present embodiment, a substrate processing apparatus 100 is configured as a film forming apparatus that forms a silicon-containing film at a low temperature on a second surface opposite to a first surface on which a device of a substrate W is formed, using capacitively coupled plasma.

The substrate processing apparatus 100 includes a chamber 10 having a substantially cylindrical shape and defining a processing space 11. The chamber 10 is made of a metal, e.g., aluminum whose surface is anodically oxidized, and is grounded.

A cylindrical metal support 14 is located at the bottom portion of the chamber 10 via an insulating plate 12, and a placing table 16 on which a substrate W made of a metal, e.g., aluminum, is placed is provided on the support 14. The placing table 16 constitutes a lower electrode. The placing table 16 has an electrostatic chuck 18 at an upper portion thereof. The electrostatic chuck 18 has a structure in which an electrode 20 is provided inside an insulator. By applying a DC voltage from a DC power supply 22 for adsorption to the electrode 20, the substrate W is attracted and held by electrostatic force such as Coulomb force. The substrate W is placed on the placing table 16 such that a gas can be supplied to the second surface.

A focus ring 24 made of a conductive material, e.g., silicon, is located around the electrostatic chuck 18. A cylindrical inner wall member 26 made of an insulator, e.g., quartz, is provided on the side surfaces of the placing table 16 and the support 14.

A coolant space 28 is provided inside the support 14, and a low-temperature coolant is circulated and supplied to the coolant space 28 from an external chiller unit (not shown) through lines 30a and 30b. The temperature of the substrate W on the placing table 16 is controlled to a temperature at which the higher-order silane gas supplied as the film forming gas liquefies, for example, a low temperature of −30 °C. Further, a heat transfer gas, e.g., He gas, is supplied to the gap between the upper surface of the electrostatic chuck 18 and the backside of the substrate W through a gas supply line 32.

An upper electrode 34 is provided above the placing table 16 serving as the lower electrode to face the placing table 16. The upper electrode 34 is supported on the upper portion of the chamber 10 via an insulating shielding member 43. The upper electrode 34 includes an electrode plate 36, which constitutes a surface facing the placing table 16 and has multiple gas injection holes 37, and an electrode support 38 of a water-cooling structure that detachably supports the electrode plate 36. The electrode plate 36 is made of a conductor, e.g., silicon. A gas diffusion space 40 is provided inside the electrode support 38, and multiple gas flow holes 41 communicating with the gas injection holes 37 extend downward from the gas diffusion space 40. A gas introducing port 42 for introducing a gas such as a film forming gas into the gas diffusion space 40 is formed in the electrode support 38, and a gas line 51 extending from a gas supply part 50 to be described later is connected to the gas introducing port 42. In other words, the upper electrode 34 is configured as a shower head for introducing a gas such as a film forming gas into the processing space 11.

A first high-frequency power supply 88 for plasma generation is electrically connected to the upper electrode 34. A matching device 87 is interposed on a power supply line 89 that supplies a power from the first high-frequency power supply 88 to the upper electrode 34. By supplying a high-frequency power from the first high-frequency power supply 88 to the upper electrode 34, capacitively coupled plasma is generated between the placing table 16 serving as the lower electrode and the upper electrode 34. A second high-frequency power supply 91 for bias application for attracting ions into the substrate W is electrically connected to the placing table 16 serving as the lower electrode. A matching device 90 is interposed on a power supply line 92 that supplies a power from the second high-frequency power supply 91 to the placing table 16 serving as the lower electrode. The matching devices 87 and 90 are used to match the load (plasma) impedance with the impedance on the first and second high-frequency power supplies 88 and 91 sides, respectively. The first high-frequency power supply 88 for plasma generation has a frequency higher than that of the second high-frequency power supply 91 for bias application.

The gas supply part 50 supplies a higher-order silane gas as a film forming gas for forming a silicon-containing film on the second surface of the substrate W. The gas supply part 50 also supplies a purge gas, a pressure adjustment gas, and a plasma generation gas composed of a rare gas such as Ar gas. In addition, H₂ gas or an oxygen-containing gas may also be supplied. The higher-order silane is represented by the general formula SiₙH₂ₙ₊₂ (n being a positive integer of 2 or more), such as Si₂H₆, Si₃H₈, and Si₄H₁₀, and any of these may be used. However, a film having a high shrinking capability can be obtained by using higher-order silane in which n is 4 or more. The gas supply part 50 has gas supply sources corresponding to multiple gases to be supplied, and individual lines extending from the respective gas supply sources are connected to the gas line 51. Each individual line is provided with an opening/closing valve and a flow rate controller.

An exhaust port 60 is provided at the bottom portion of the chamber 10, and an exhaust device 64 is connected to the exhaust port 60 via an exhaust line 62. The exhaust device 64 includes an automatic pressure control valve and a vacuum pump, and evacuates the inside of the chamber 10 to a desired vacuum level. A loading/unloading port 65 for loading and unloading the substrate W into and from the chamber 10 is provided on the sidewall of the chamber 10, and the loading/unloading port 65 is opened and closed by a gate valve 66.

The substrate processing apparatus 100 has a control part 70. The control part 70 is configured as a computer, and includes a main controller having a CPU, an input device (keyboard, mouse, or the like), an output device (printer, or the like), a display device (display, or the like), and a storage device (storage medium). The main controller controls the high-frequency power supplies 88 and 91, the opening/closing valves and flow rate controllers of the gas supply part 50, the automatic pressure control valve, the DC power supply 22 for adsorption, the chiller unit, and the gate valve 66, for example. The control operations performed by the main controller are executed according to a processing recipe that is a control program stored in a storage medium (hard disk, optical disk, semiconductor memory, or the like) built in the storage device.

In the substrate processing apparatus 100 configured as described above, the substrate W is loaded into the chamber 10 and placed on the placing table 16 with the second surface facing upward. Then, an inert gas is supplied into the chamber 10 from the gas supply part 50, and the inside of the chamber 10 is adjusted to a depressurized state by the exhaust device 64. In this state, a plasma generation gas, e.g., Ar gas, is supplied into the chamber 10 from the gas supply part 50, and the high-frequency power for plasma generation is applied from the first high-frequency power supply 88 to the upper electrode 34. As a result, capacitively coupled plasma is produced between the upper electrode 34 and the placing table 16 serving as the lower electrode. The plasma generation gas may also be used as the inert gas for pressure adjustment. Further, the high-frequency power for bias application for attracting ions is applied from the second high-frequency power supply 91 to the placing table 16.

In this state, by supplying a higher-order silane gas serving as the film forming gas into the chamber 10 from the gas supply part 50, the higher-order silane gas is excited by the plasma. The excited higher-order silane gas reaches the second surface of the substrate W maintained at a temperature at which the higher silane liquefies, for example −30 °C, and the film formation proceeds by gas-phase polymerization at such a low temperature. As a result, a silicon-containing film having a high shrinking capability as described above and capable of generating large stress on the second surface of the substrate W is formed.

### Substrate Processing Method

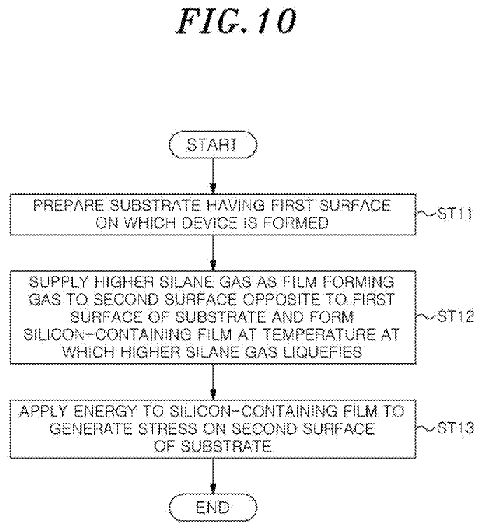

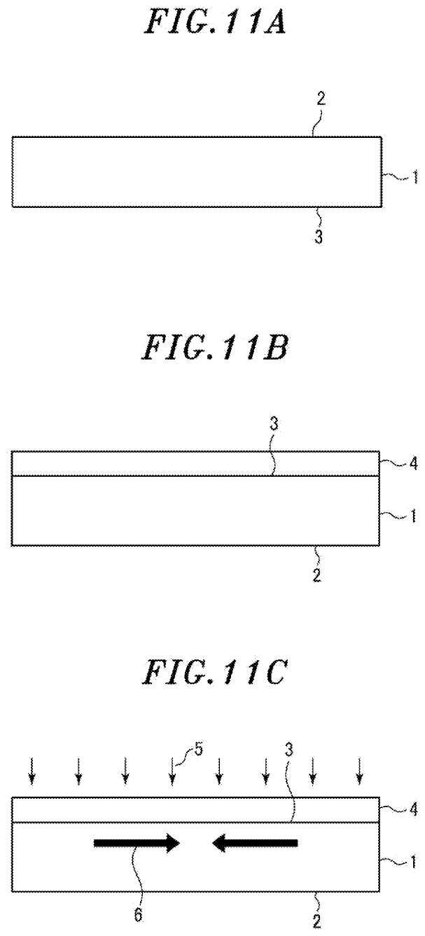

FIG. 10 is a flowchart illustrating a substrate processing method according to the second embodiment. FIGS. 11A to 11C are process cross-sectional views thereof.

In the present embodiment, first, a substrate 1 having a first surface 2 on which a device is formed is prepared (step ST11, FIG. 11A). Next, a higher-order silane gas is supplied as a film forming gas to a second surface 3 opposite to the first surface 2 of the substrate 1, and a silicon-containing film 4 is formed at a temperature at which the higher-order silane gas liquefies (step ST12, FIG. 11B). Next, energy 5 is applied to the silicon-containing film 4 to generate stress 6 on the second surface 3 of the substrate 1 (step ST13, FIG. 11C).

In the present embodiment, step ST11 and step ST12 are performed in the same manner as step ST1 and step ST2 of the first embodiment.

In step ST13, the energy 5 is applied to the silicon-containing film 4 to generate the stress 6 on the second surface 3 of the substrate 1. In other words, the stress 6 is generated on the second surface 3 of the substrate 1 by a force produced when the silicon-containing film 4 shrinks due to the application of energy to the silicon-containing film 4. As described above, the silicon-containing film 4 has high shrinking capability, and thus can generate large stress. By generating stress on the second surface 3 of the substrate 1, it is possible to reduce the stress generated in the substrate 1 due to film formation during the process of forming a device on the first surface 2. In addition, by generating stress on the second surface 3 of the substrate 1, the substrate 1 can be actively strained.

The method of applying energy to the silicon-containing film 4 is not particularly limited, and thermal energy, optical energy, or the like can be used. In step ST13, by adjusting the amount of energy applied to the silicon-containing film 4, the amount of shrinkage of the silicon-containing film 4 can be adjusted to control the stress generated on the second surface 3 of the substrate 1.

Annealing can be used as a method for applying energy to the silicon-containing film. During the annealing, stress adjustment can be performed by adjusting the amount of energy by controlling the annealing temperature and/or the annealing time, for example. The annealing may be thermal annealing or optical annealing. The annealing may be performed using various devices such as a resistance heating element, a heating lamp, an LED, or a UV light source. The annealing temperature may be 100 °C to 400 °C, and is particularly effective at 100 °C to 200 °C. The annealing time may be 10 seconds to 12 hours, and may be about one hour, for example.

In the case of a technique such as that disclosed in Japanese Laid-open Patent Publication No. 2020-150133 in which a film that generates stress in the substrate is formed on the second surface of the substrate by general CVD or ALD, it is difficult to adjust the stress after the film is formed. However, in the present embodiment, the stress generated in the substrate can be adjusted by a simple method such as annealing.

In step ST13, energy may be applied to the entire silicon-containing film 4, or may be applied locally to the silicon-containing film 4. By applying energy to the entire film, the silicon-containing film 4 shrinks as a whole, and stress can be generated over the entire second surface 3 of the substrate 1. By applying energy locally, only a part of the silicon-containing film 4 to which energy is applied shrinks, and stress can be generated locally only at a portion of the second surface 3 of the substrate 1 corresponding to the part. By generating stress locally, for example, local stress on the first surface 2 of the substrate 1 can be reduced.

After stress is generated on the second surface 3 of the substrate 1, the silicon-containing film 4 may remain or may be removed. In other words, the silicon-containing film 4 may become unnecessary after stress is generated in the substrate 1 and a device is formed on the first surface 2. However, even if the silicon-containing film 4 remains, it does not adversely affect the device, which can save the trouble of removal. In addition, the silicon-containing film 4 can be easily removed when necessary, and the removal thereof provides advantages such as thinning of the overall structure and improvement of flatness. Therefore, whether to remove or leave the silicon-containing film 4 may be determined based on the requirements during device formation. In the case of removing the silicon-containing film 4, a process of removing the silicon-containing film 4 is performed after the process of applying energy 5 to the silicon-containing film 4 to generate stress 6 on the second surface 3 of the substrate 1 (step ST13).

### Substrate Processing System

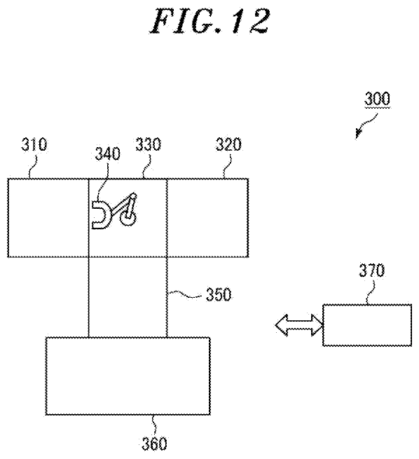

FIG. 12 is a schematic plan view illustrating an example of a substrate processing system used for implementing the second embodiment. A substrate processing system 300 shown in FIG. 12 is a cluster structure (multi-chamber type) system, and includes a substrate processing apparatus 310, an annealing apparatus 320, a transfer chamber 330, a transfer device 340, a load-lock chamber 350, a loader module 360, and an overall control part 370.

The substrate processing apparatus 310 supplies a higher-order silane gas as a film forming gas to the second surface of the substrate W at a temperature at which the gas liquefies and forms a silicon-containing film on the second surface. The substrate processing apparatus 310 may be configured in the same manner as the substrate processing apparatus 100 of the first embodiment.

The annealing apparatus 320 is used for annealing the silicon-containing film formed on the second surface of the substrate to apply energy to the silicon-containing film and generate stress on the second surface of the substrate W. An example of the annealing apparatus 320 will be described later.

The transfer chamber 330 is maintained in a predetermined vacuum atmosphere, and a transfer device 340 for transferring the substrate W is provided therein. The substrate processing apparatus 310, the annealing apparatus 320, and the load-lock chamber 350 are connected to the transfer chamber 330 via gate valves (not shown). The transfer device 340 transfers the substrate W between the substrate processing apparatus 310, the annealing apparatus 320, and the load-lock chamber 350.

The load-lock chamber 350 is provided between the loader module 360 and the transfer chamber 330, and an inner atmosphere thereof can be switched between an atmospheric atmosphere and a vacuum atmosphere. The loader module 360 is adjacent to the load-lock chamber 350 and connected thereto via a gate valve (not shown), and is maintained in an atmospheric atmosphere. A transfer device (not shown) is provided in the loader module 360. A load port is provided on a wall of the loader module 360 opposite to the wall facing the load-lock chamber 350, and a carrier (e.g., a front opening unified pod (FOUP)) that accommodates the substrate W or is empty is attached to the load port. The transfer device of the loader module 360 transfers the substrate W between the load-lock chamber 350 and the carrier attached to the load port.

The overall control part 370 is configured as a computer, and includes a main controller having a CPU, an input device (keyboard, mouse, or the like), an output device (printer, or the like), a display device (display, or the like), and a storage device (storage medium). The main controller controls processing of the substrate processing apparatus 310 and the annealing apparatus 320, transfer operations of the transfer device 340 and the transfer device of the loader module 360, opening and closing of gate valves, and the like. The overall control part 370 may be configured as a higher-level control part of the controllers of the substrate processing apparatus 310 and the annealing apparatus 320.

In the substrate processing system 300, first, the substrate W is taken out from the carrier connected to the load port by the transfer device (not shown) in the loader module 360, and is loaded into the load-lock chamber 350 in an atmospheric atmosphere.

Then, the load-lock chamber 350 is set to a vacuum atmosphere, and the substrate W in the load-lock chamber 350 is loaded into the substrate processing apparatus 310 by the transfer device 340. In the substrate processing apparatus 310, a higher-order silane gas as a film forming gas is supplied to the second surface of the substrate W at a temperature at which the gas liquefies, thereby forming a silicon-containing film on the second surface. Thereafter, the substrate W having the silicon-containing film is unloaded from the substrate processing apparatus 310 by the transfer device 340 and loaded into the annealing apparatus 320. In the annealing apparatus 320, the silicon-containing film formed on the second surface of the substrate W shrinks by annealing, thereby generating stress on the second surface of the substrate. Thereafter, the annealed substrate W is unloaded by the transfer device 340 and transferred to the load-lock chamber 350.

Then, the load-lock chamber 350 is set to an atmospheric atmosphere, and the substrate W in the load-lock chamber 350 is returned to the carrier by the transfer device in the loader module 360.

The processes described above are performed simultaneously for multiple substrates W, thereby completing the processing of the multiple substrates W in the carrier.

### Annealing Apparatus

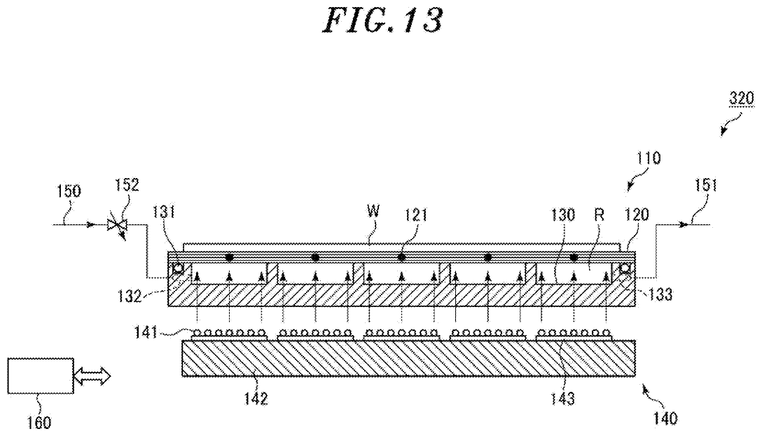

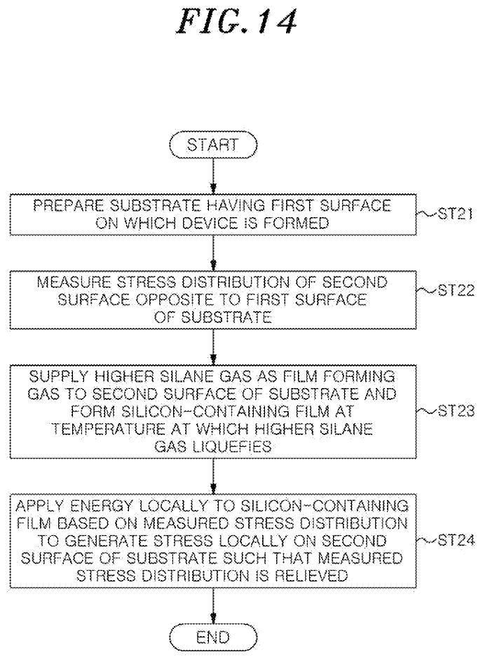

FIG. 13 is a cross-sectional view illustrating an example of the annealing apparatus 320.

The annealing apparatus 320 includes a chamber (not shown), a placing table 110 that is provided in the chamber and places the substrate W thereon, a heating mechanism 140 for performing heating using LEDs, and a control part 160.

The placing table 110 includes a top plate 120 serving as a ceiling plate, and a channel forming member 130. The top plate 120 is attached on the channel forming member 130 via a seal ring 131. The substrate W has a silicon-containing film formed on the second surface, and is attracted and held on the surface of the top plate 120 with the silicon-containing film facing downward.

Multiple temperature sensors 121 are embedded in the top plate 120 while being spaced apart from each other in plan view. The top plate 120 is formed in a disk shape having a diameter similar to that of the substrate W, and is made of SiC, for example. SiC has high thermal conductivity and Young's modulus, and also has high absorption efficiency for light from LEDs 141 of the heating mechanism 140 to be described later, which allows efficient heating using the light from the heating mechanism 140.

The channel forming member 130 is formed in a disk shape having a diameter that is substantially the same as that of the top plate 120, and is made of a material transparent to the wavelength of light from LEDs to be described later. A groove for allowing a temperature control medium to flow is formed in the upper portion of the channel forming member 130. The groove is covered by the top plate 120 to form a temperature control medium channel R. A supply port 132 for supplying the temperature control medium to the temperature control medium channel R and a discharge port 133 for discharging the temperature control medium are formed at the side portion of the channel forming member 130. A temperature control medium supply line 150 and a temperature control medium discharge line 151 are connected to the supply port 132 and the discharge port 133, respectively, and the temperature control medium is supplied to and circulated in the temperature control medium channel R. A valve 152 is provided in the temperature control medium supply pipe 150. By allowing the temperature control medium having a predetermined temperature to flow through the temperature control medium channel R, the base temperature of the placing table 110 is adjusted to a predetermined temperature.

The heating mechanism 140 is configured as a light irradiation mechanism, and is located to face the surface opposite to the substrate placing surface of the placing table 110, that is, the bottom surface of the channel forming member 130, so as to correspond to the substrate W placed on the top plate 120. The heating mechanism 140 has the multiple LEDs 141 serving as a heating source, and irradiates light from the LEDs onto the top plate 120 of the placing table 110 to heat the silicon-containing film of the substrate W placed thereon via the top plate 120.

Each LED 141 emits near-infrared light, for example. The light emitted from the LEDs 141 passes through the channel forming member 130 of the placing table 110, which is made of a light-transmitting member. The temperature control medium flowing through the temperature control medium channel R is made of a material that transmits the light from the LEDs 141, and the light that has passed through the channel forming member 130 and the temperature control medium is incident on the top plate 120. When the light from the LEDs 141 is near-infrared light, polycarbonate, quartz, polyvinyl chloride, acrylic resin, or glass may be used for the light-transmitting member constituting the channel forming member 130.

The heating mechanism 140 is formed by arranging multiple LED units 143 on a base portion 142 with substantially no gap therebetween. Each LED unit 143 includes the multiple LEDs 141 serving as a heating source and arranged in a unit. The LED units 143 can individually and independently perform on/off control and light intensity control, and thus can heat the substrate W uniformly or locally. Further, the annealing temperature of the substrate W can be controlled by controlling the light intensity of the LEDs 141 of the LED units 143. The base portion 142 may be provided with a coolant channel and may be cooled by a coolant.

The control part 160 is configured as a computer, and includes a main control unit having a CPU, an input device (keyboard, mouse, or the like), an output device (printer, or the like), a display device (display, or the like), and a storage device (storage medium). The main controller performs, e.g., the on/off control and light intensity control of the LEDs 141 for each LED unit 143, the flow rate control of the temperature control medium, and the like. The control operations performed by the main controller are executed according to a processing recipe that is a control program stored in a storage medium (hard disk, optical disk, semiconductor memory, or the like) built in the storage device.

With the annealing apparatus 320 configured as described above, the annealing can be performed on the entire or a part of the silicon-containing film formed on the second surface of the substrate W to shrink the silicon-containing film, thereby generating stress on the entire or a part of the second surface of the substrate W.

The substrate processing system 300 described above is an example where processes are performed in-situ using a cluster structure system in which an apparatus for forming a silicon-containing film and an apparatus for performing annealing for stress generation are connected to a transfer chamber. However, the substrate processing system is not limited thereto and may be configured by separately providing these apparatuses. Further, the annealing apparatus is not limited to one using LEDs, and may be a resistance heating element, a heating lamp, or a UV light source. Moreover, the apparatus is not limited to an annealing apparatus as long as it can apply energy to the silicon-containing film.

### Third Embodiment

### Substrate Processing Method

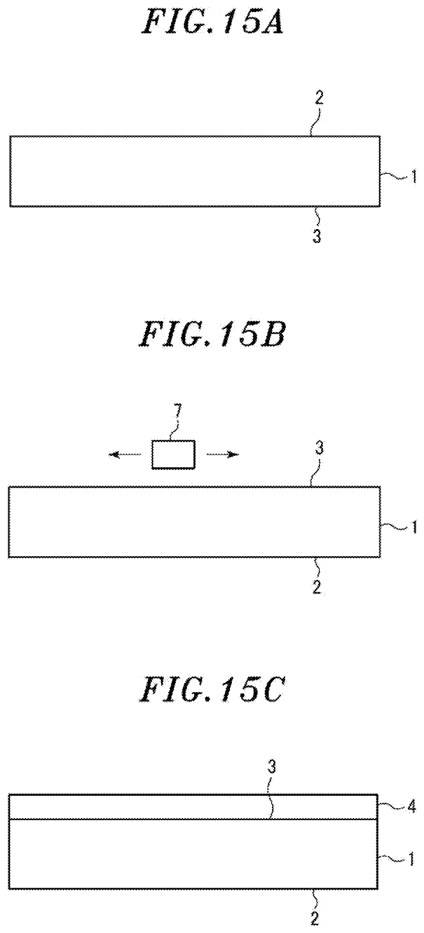

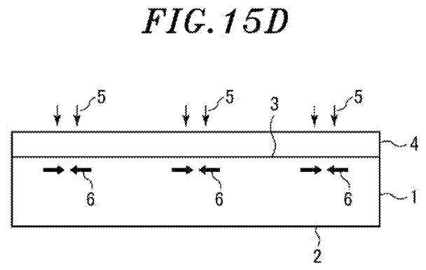

FIG. 14 is a flowchart illustrating a substrate processing method according to a third embodiment. FIGS. 15A to 15D are process cross-sectional views thereof.

In the present embodiment, first, the substrate 1 having the first surface 2 on which a device is to be formed is prepared (step ST21, FIG. 15A). Next, stress distribution of the second surface 3 opposite to the first surface 2 of the substrate 1 is measured (step ST22). The measurement of the stress distribution may be performed on the entire or a part of the second surface 3 of the substrate 1. For example, as shown in FIG. 15B, the stress distribution can be measured by scanning a stress measuring part 7 over the second surface 3 of the substrate 1. Next, a higher-order silane gas as a film forming gas is supplied to the second surface 3 of the substrate 1, thereby forming the silicon-containing film 4 at a temperature at which the higher-order silane gas liquefies (step ST23, FIG. 15C). Next, in accordance with the stress distribution measured in step ST22, the energy 5 is locally applied to the silicon-containing film 4 to locally generate stress 6 on the second surface 3 of the substrate 1 such that the measured stress distribution is reduced (step ST24, FIG. 15D).

In the present embodiment, step ST21 and step ST23 are performed in the same manner as step ST1 and step ST2 of the first embodiment.

In step ST22, the method for measuring the stress distribution of the second surface 3 of the substrate 1 is not particularly limited, but the measurement using Raman spectroscopy may be used. For example, when the substrate is a Si substrate, the stress of the substrate 1 can be calculated from the shift amount (Raman Shift) from 520 (cm⁻¹), which is the peak of Si crystal (stress-free crystal), after obtaining the spectrum of Raman scattered light (Raman spectrum) by irradiating the substrate 1 with laser light, according to the above Eq. (1). The stress distribution of the second surface 3 of the substrate 1 can be measured by scanning the laser light over the second surface 3 using a stress measuring part having a laser light source, an objective lens, a spectrometer, a detector, and the like. In other words, the stress distribution can be obtained by scanning the laser light over the second surface 3 of the substrate 1, measuring the Raman spectrum from Raman scattered light, obtaining the Raman shift of the silicon peak at each position on the second surface 3 of the substrate 1, and calculating the stress at each position.

In step ST24, based on the stress distribution of the second surface 3 of the substrate 1 measured in step ST22, the energy is locally applied to the silicon-containing film 4 to shrink the film, thereby generating stress on the second surface 3 of the substrate 1 such that the measured stress distribution is relieved. In other words, in step ST24, the energy is locally applied to the silicon-containing film 4 to generate stress at the portion of the second surface 3 of the substrate 1 where the stress was measured, thereby relieving the stress distribution. As a method for locally applying energy, for example, the above-described local annealing using LEDs may be used. Alternatively, local annealing may be performed by scanning a UV light source or a heating lamp.

As described above, conventionally, in the case of forming a device on one surface (the first surface) of a wafer as a substrate, film formation and pattern formation by etching are repeated. Recently, the formed patterns are complex, and after or during the formation of a device having a desired pattern, complex stress is generated in the film constituting the pattern, which leads to complex and non-uniform stress distribution in the substrate.

Therefore, in the present embodiment, the stress distribution of the second surface 3 of the substrate 1 is measured and, then, the silicon-containing film 4 having a high shrinking capability as described above is formed. Then, local annealing or the like is performed on the silicon-containing film 4 according to the measured stress distribution. Due to the local annealing or the like, the portions of the silicon-containing film 4 subjected to the annealing shrink, thereby generating local stress on the second surface 3 of the substrate 1 such that the measured stress distribution of the substrate is relieved.

A stress-relief film formed on the second surface of a substrate by general CVD or ALD, which is disclosed in Japanese Laid-open Patent Publication No. 2020-150133, cannot cope with the complex and non-uniform stress distribution caused by such patterns. In order to use such techniques for relieving non-uniform stress distributions, pattern formation using, e.g., photolithography technology, is required for the stress-relief film, resulting in an extremely complicated process with limited effects. In contrast, in the present embodiment, non-uniform stress distribution can be relieved by a simple method of performing annealing in accordance with the measured stress distribution. In addition, in the present embodiment, large stress can be generated by shrinking the silicon-containing film, and the magnitude of the generated stress can be adjusted. Hence, it is possible to provide a significant stress relief effect for the non-uniform stress distribution.

### Substrate Processing System

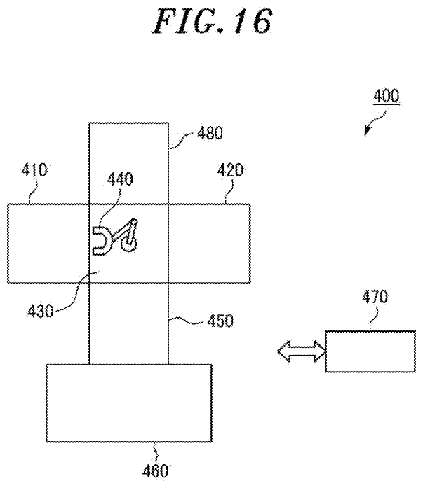

FIG. 16 is a schematic plan view illustrating an example of a substrate processing system used for implementing the third embodiment. The substrate processing system 400 shown in FIG. 16 is a cluster structure (multi-chamber type) system, and includes a substrate processing apparatus 410, an annealing apparatus 420, a stress measuring apparatus 480, a transfer chamber 430, a transfer device 440, a load-lock chamber 450, a loader module 460, and an overall control part 470.

In the substrate processing apparatus 410, a higher-order silane gas as a film forming gas is supplied to the second surface of the substrate W at a temperature at which the gas liquefies to form a silicon-containing film on the second surface of the substrate W. The substrate processing apparatus 410 may be configured in the same manner as the substrate processing apparatus 100 of the first embodiment.

The annealing apparatus 420 locally anneals the silicon-containing film formed on the second surface of the substrate W in accordance with the stress distribution measured by the stress measuring apparatus 480 described below, thereby locally generating stress on the second surface of the substrate W such that the measured stress is relieved. The annealing apparatus 420 may be configured in the same manner as the annealing apparatus 320 of the second embodiment, which is capable of performing local annealing.

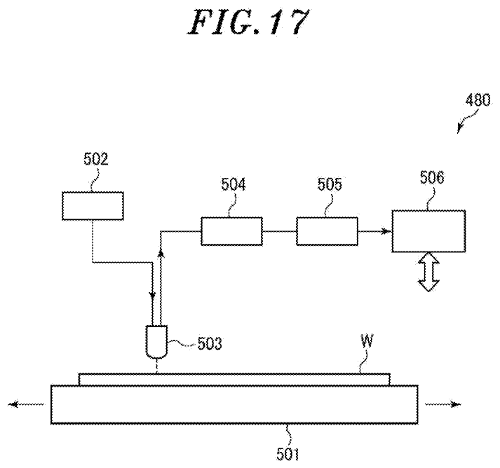

The stress measuring apparatus 480 includes, as shown in FIG. 17, for example, a stage 501 on which the substrate W is placed, a laser light source 502, an objective lens 503, a spectrometer 504, a multichannel detector 505 for measuring a spectrum, and a control part 506. The substrate W is placed on the stage 501 with the second surface facing upward. The stage 501 is movable in a plane, and allows the second surface of the substrate W to be scanned with the laser light. The optical system may be moved to scan the laser light. The laser light from the laser light source 502 is irradiated onto the second surface of the substrate W through the objective lens 503. Raman scattered light generated from the second surface of the substrate W is collected by the objective lens 503 and guided to the spectroscope 504, and the Raman spectrum is measured by the multichannel detector 505. The control part 506 controls individual components of the stress measuring apparatus 480 and functions as a calculation part. The control part 506 obtains the Raman shift of the silicon peak from the Raman spectrum and calculates the stress.

The transfer chamber 430 is maintained in a predetermined vacuum atmosphere, and a transfer device 440 for transferring the substrate W is provided therein. The substrate processing apparatus 410, the annealing apparatus 420, the stress measuring apparatus 480, and the load-lock chamber 450 are connected to the transfer chamber 430 via gate valves (not shown). The transfer device 440 transfers the substrate W among the substrate processing apparatus 410, the annealing apparatus 420, the stress measuring apparatus 480, and the load-lock chamber 450.

The load-lock chamber 450 and the loader module 460 are configured in the same manner as the load-lock chamber 350 and the loader module 360 of the substrate processing system 300 of the second embodiment. A transfer device is provided in the loader module 460, and the transfer device transfers the substrate W between the load-lock chamber 450 and the carrier attached to the load port.

The overall control part 470 is configured as a computer, and is configured in the same manner as the overall control part 370 in the substrate processing system 300 of the second embodiment. The overall control part 470 controls the processing of the substrate processing apparatus 410, the annealing apparatus 420, and the stress measuring apparatus 480, the transfer operations of the transfer device 440 and the transfer device of the loader module 460, opening and closing of gate valves, and the like. In addition, the overall control part 470 stores the stress distribution measured by the stress measuring apparatus 480 and issues instructions to the annealing apparatus 420 regarding the portion to be annealed in accordance with the stress distribution. The overall control part 470 may be configured as a higher-level control part of the controllers of the substrate processing apparatus 410, the annealing apparatus 420, and the stress measuring apparatus 480.

In the substrate processing system 400, first, the substrate W is taken out from the carrier connected to the load port by the transfer device (not shown) in the loader module 460 and is loaded into the load-lock chamber 450 in an atmospheric atmosphere. The substrate W may have a device formed on the first surface or may have a pattern formed in the middle of the process of forming a device.

Then, the load-lock chamber 450 is set to a vacuum atmosphere, and the substrate W in the load-lock chamber 450 is loaded into the stress measuring apparatus 480 with the second surface facing upward by the transfer device 440. In the stress measuring apparatus 480, the stress distribution over the entire or a part of the second surface of the substrate W is measured. The measurement result of the stress distribution is stored in the overall control part 470. Thereafter, the substrate W that has been subjected to the stress distribution is unloaded from the stress measuring apparatus 480 by the transfer device 440 and loaded into the substrate processing apparatus 410. In the substrate processing apparatus 410, a higher-order silane gas as a film forming gas is supplied to the second surface of the substrate W at a temperature at which the gas liquefies, thereby forming a silicon-containing film on the second surface. Thereafter, the substrate W on which the silicon-containing film has been formed is unloaded from the substrate processing apparatus 410 by the transfer device 440 and loaded into the annealing apparatus 420. In the annealing apparatus 420, the local annealing is performed on the silicon-containing film 4 in accordance with the stress distribution measurement result obtained by the stress measuring apparatus 480 and stored in the overall control part 470. Due to the local annealing, the annealed portions of the silicon-containing film shrink, thereby generating local stress on the second surface of the substrate W such that the stress distribution of the substrate W measured by the stress measuring apparatus 480 is relieved. Thereafter, the annealed substrate W is unloaded by the transfer device 440 and transferred to the load-lock chamber 450.

Then, the load-lock chamber 450 is set to an atmospheric atmosphere, and the substrate W in the load-lock chamber 450 is returned to the carrier by the transfer device in the loader module 460.

The above processing is performed simultaneously for multiple substrates W, thereby completing the processing of the multiple substrates W in the carrier.

The substrate processing system 400 described above is an example where processes are performed in-situ using a cluster structure system in which an apparatus for forming a silicon-containing film, an apparatus for performing annealing for stress generation, and a stress measuring apparatus are connected to a transfer chamber. However, the substrate processing system is not limited thereto, and may be formed by separately providing these apparatuses. Further, the annealing apparatus is not limited to one using LEDs, and any apparatus capable of performing local heating may be used. A UV light source or a heating lamp may be used. Moreover, the apparatus is not limited to an annealing apparatus as long as it can apply energy to the silicon-containing film.

### Other Applications

While the embodiments of the present disclosure have been described, the embodiments of the present disclosure are illustrative in all respects and are not restrictive. The above-described embodiments may be omitted, replaced, or changed in various forms without departing from the scope of the appended claims and the gist thereof.

For example, in the above embodiments, a Si film and a SiO₂ film are described as examples of the silicon-containing film formed on the second surface of the substrate. However, the present disclosure is not limited thereto, and other Si-containing films such as a SiN film may also be used.

Further, in the above embodiments, an apparatus in which the substrate is cooled by the placing table and processes using capacitively coupled plasma has been described as an example of the substrate processing apparatus for forming the silicon-containing film. However, the present disclosure is not limited thereto. For example, the method for cooling the substrate is not limited to a cooling method using a placing table as long as film formation can be performed at a temperature at which the higher-order silane gas liquefies. In addition, the plasma is not limited to capacitively coupled plasma, and inductively coupled plasma or microwave plasma may also be used. Alternatively, remote plasma may also be used. Further, film formation may be performed by a method that does not use plasma as long as film formation can be performed at a temperature at which the higher-order silane gas liquefies.

Further, the annealing apparatus and the stress measuring apparatus described above are merely examples, and the configurations thereof are not limited as long as the intended purpose can be achieved.

1. A substrate processing method comprising:
preparing a substrate having a first surface on which a device is to be formed; and
forming a silicon-containing film on a second surface opposite to the first surface of the substrate using a higher-order silane gas as a film forming gas at a temperature at which the higher-order silane gas liquefies.

2. The substrate processing method of claim 1, wherein in said forming the silicon-containing film, the substrate is placed on a placing table in a chamber, the placing table is maintained at a temperature at which the higher-order silane gas liquefies, and the higher-order silane gas is introduced into the chamber and supplied to the second surface of the substrate, thereby forming the silicon-containing film on the second surface.

3. The substrate processing method of claim 2, wherein the higher-order silane gas is supplied to the second surface of the substrate in a plasma-excited state.

4. The substrate processing method of claim 1, further comprising:
after said forming the silicon-containing film, generating stress on the second surface of the substrate by applying energy to the silicon-containing film.

5. The substrate processing method of claim 4, wherein when the energy is applied to the silicon-containing film, the silicon-containing film shrinks, thereby generating the stress on the second surface of the substrate.

6. The substrate processing method of claim 5, wherein when the stress is generated on the second surface of the substrate, the stress generated on the second surface of the substrate is controlled by controlling the amount of shrinkage of the silicon-containing film depending on the amount of energy applied to the silicon-containing film.

7. The substrate processing method of claim 5, wherein when the stress is generated on the second surface of the substrate, the energy is applied to the silicon-containing film by annealing the silicon-containing film.

8. The substrate processing method of claim 7, wherein when the stress is generated on the second surface of the substrate, the stress generated on the second surface of the substrate is controlled by controlling the amount of shrinkage of the silicon-containing film by a temperature and/or time of the annealing.

9. The substrate processing method of claim 4, further comprising:
before said forming the silicon-containing film, measuring stress distribution of the second surface,
wherein said generating stress on the second surface of the substrate by applying energy to the silicon-containing film includes applying the energy locally to the silicon-containing film according to the measured stress distribution to locally generate stress on the second surface of the substrate such that the measured stress distribution is relieved.

10. The substrate processing method of claim 9, wherein said measuring stress distribution of the second surface includes calculating the stress on the second surface of the substrate from a shift amount of a crystal peak of a Raman spectrum obtained by Raman spectroscopy.

11. The substrate processing method of claim 9, wherein said generating stress on the second surface of the substrate by applying energy to the silicon-containing film is performed by locally heating the silicon-containing film by turning on/off LED units serving as a heating source and arranged to correspond to the silicon-containing film formed on the second surface of the substrate, each LED unit including multiple LEDs arranged in a unit.

12. A substrate processing apparatus comprising:
a chamber accommodating a substrate having a first surface on which a device is to be formed;
a placing table that places the substrate such that a gas is supplied to a second surface opposite to the first surface;
a gas supply part configured to supply a higher-order silane gas as a film forming gas to the substrate; and
a cooling device configured to cool the substrate to a temperature at which the higher-order silane gas liquefies via the placing table,
wherein the higher-order silane gas is supplied to the second surface of the substrate to form a silicon-containing film on the second surface of the substrate.

13. The substrate processing apparatus of claim 12, further comprising:
a plasma generation device configured to excite the higher-order silane gas.

14. A substrate processing system comprising:
the substrate processing apparatus described in claim 12; and
an apparatus configured to apply energy to the silicon-containing film formed by the substrate processing apparatus to generate stress on the second surface of the substrate.

15. The substrate processing system of claim 14, wherein the apparatus configured to apply energy to the silicon-containing film to generate stress on the second surface of the substrate is an annealing apparatus.

16. The substrate processing system of claim 15, wherein the annealing apparatus controls stress generated on the second surface of the substrate by a temperature and/or time of the annealing.

17. The substrate processing system of claim 14, further comprising:
a stress measuring apparatus configured to measure stress distribution of the second surface before the silicon-containing film is formed by the substrate processing apparatus,
wherein the apparatus configured to apply energy to the silicon-containing film to generate stress on the second surface locally applies energy to the silicon-containing film according to the measured stress distribution to locally generate stress on the second surface of the substrate such that the measured stress distribution is relieved.

18. The substrate processing system of claim 17, wherein the stress measuring apparatus calculates stress on the second surface of the substrate from a shift amount of a crystal peak of a Raman spectrum obtained by Raman spectroscopy.

19. The substrate processing system of claim 17, wherein the apparatus configured to apply energy to the silicon-containing film to generate stress on the second surface includes a heating source formed by arranging multiple LED units to correspond to the silicon-containing film formed on the second surface of the substrate, each LED unit including multiple LEDs arranged in a unit, and the silicon-containing film is locally heated by turning on/off the LED units.
